(19) United States
(12) Patent Application Publication
(10) Pub. No.: US 2021/0235599 A1
(43) Pub. Date: Jul. 29, 2021

(54) REVERSIBLE AIR MOVER FOR MODULAR PROCESSING UNIT

(71) Applicant: Dell Products L.P., Hopkinton, MA (US)

(72) Inventors: Patrick V. Illingworth, Leander, TX (US); Eduardo Escamilla, Round Rock, TX (US)

(21) Appl. No.: 16/775,832

(22) Filed: Jan. 29, 2020

(51) Int. Cl. H05K 7/20; H05K 7/14

(52) U.S. Cl. CPC H05K 7/20736; H05K 7/1489; H05K 7/20172

(57) ABSTRACT

A method for installing a modular processing unit in a modular compute unit, where the method includes identifying a desired orientation of the modular processing unit, identifying a gaseous flow direction of the modular compute unit, making a determination, based on the desired orientation and the gaseous flow direction, that an air mover of the modular processing unit needs to be reversed, reversing, based on the determination, the air mover, and affixing the modular processing unit to the modular compute unit.

### BACKGROUND

Devices and/or components of devices are often capable of performing certain functionalities that other devices and/or components are not configured to perform and/or are not capable of performing. In such scenarios, it may be desirable to adapt one or more systems to enhance the functionalities of devices and/or components that cannot perform the one or more functionalities.

### SUMMARY

In general, in one aspect, the invention relates to an equipment rack that includes a modular compute unit, a modular processing unit disposed in the modular compute unit, an air mover unit disposed in the modular processing unit, where the modular processing unit includes an air mover and an air mover holder.

In general, in one aspect, the invention relates to a method for installing a modular processing unit in a modular compute unit, where the method includes identifying a desired orientation of the modular processing unit, identifying a gaseous flow direction of the modular compute unit, making a determination, based on the desired orientation and the gaseous flow direction, that an air mover of the modular processing unit needs to be reversed, reversing, based on the determination, the air mover, and affixing the modular processing unit to the modular compute unit.

Other aspects of the invention will be apparent from the following description and the appended claims.

### BRIEF DESCRIPTION OF DRAWINGS

FIG. 1 shows an example equipment rack, in accordance with one or more embodiments of the invention.

FIG. 2 shows an example modular compute unit, in accordance with one or more embodiments of the invention.

FIG. 3 shows a diagram of an exterior of a modular processing unit, in accordance with one or more embodiments of the invention.

FIG. 4 shows a diagram of an air mover unit, in accordance with one or more embodiments of the invention.

FIG. 5 shows a diagram of a modular processing unit, in accordance with one or more embodiments of the invention.

FIG. 6 shows a flowchart of a method of installing a modular processing unit, in accordance with one or more embodiments of the invention.

### DETAILED DESCRIPTION

Specific embodiments will now be described with reference to the accompanying figures. In the following description, numerous details are set forth as examples of the invention. One of ordinary skill in the art, having the benefit of this detailed description, would appreciate that one or more embodiments of the present invention may be practiced without these specific details and that numerous variations or modifications may be possible without departing from the scope of the invention. Certain details known to those of ordinary skill in the art may be omitted to avoid obscuring the description.

In the following description of the figures, any component described with regard to a figure, in various embodiments of the invention, may be equivalent to one or more like-named components shown and/or described with regard to any other figure. For brevity, descriptions of these components may not be repeated with regard to each figure. Thus, each and every embodiment of the components of each figure is incorporated by reference and assumed to be optionally present within every other figure having one or more like-named components. Additionally, in accordance with various embodiments of the invention, any description of any component of a figure is to be interpreted as an optional embodiment, which may be implemented in addition to, in conjunction with, or in place of the embodiments described with regard to a corresponding like-named component in any other figure.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the term ‘operatively connected’, or ‘operative connection’, means that there exists between elements/components/devices a direct or indirect connection that allows the elements to interact with one another in some way (e.g., via the exchange of information). For example, the phrase ‘operatively connected’ may refer to any direct (e.g., wired or wireless connection directly between two devices) or indirect (e.g., wired and/or wireless connections between any number of devices connecting the operatively connected devices) connection.

In general, embodiments of the invention relate to systems and methods for providing a removably attachable air mover to a modular processing unit that, once removed, may be reversed and re-attached to the modular processing unit. Thus, the modular processing unit may be installed at various orientations in a modular compute unit, regardless of the existing direction of gaseous flow. That is, a modular processing unit may installed in a preferred direction, and the air mover of that modular processing unit can be oriented to match the direction of the already-existing gaseous flow.

The invention may provide one or more advantages. In one embodiment of the invention, manufacturing of modular processing unit becomes less burdensome and/or costly because, instead of manufacturing two different modular processing units (each allowing for gaseous flow in opposite directions), a single modular processing unit may be manufactured that allows an installer to reverse the air mover, as needed, to match the configuration of the system in which the modular processing unit is being installed.

Another advantage of various embodiments of a reversible modular air mover is the installer and/or end users of the modular processing unit are provided flexibility and customizability of the configuration of the modular compute unit (in which the modular processing unit is installed). That is, without the ability to re-orient (reverse) a modular processing unit, the geometric configuration of devices within the modular compute unit is limited. However, as one embodiment of the invention proposes, a modular processing unit may be installed in either the front or back of a modular compute unit, thereby providing additional options for the layout of a modular compute unit.

Another advantage of various embodiments of a reversible modular air mover is that servicing and replacement of the air mover becomes easier. As the air mover is designed to easily detach—replacing, upgrading, testing, or generally servicing the air mover also becomes less burdensome compared an air mover that is more permanently affixed. The invention is not limited to the aforementioned advantages.

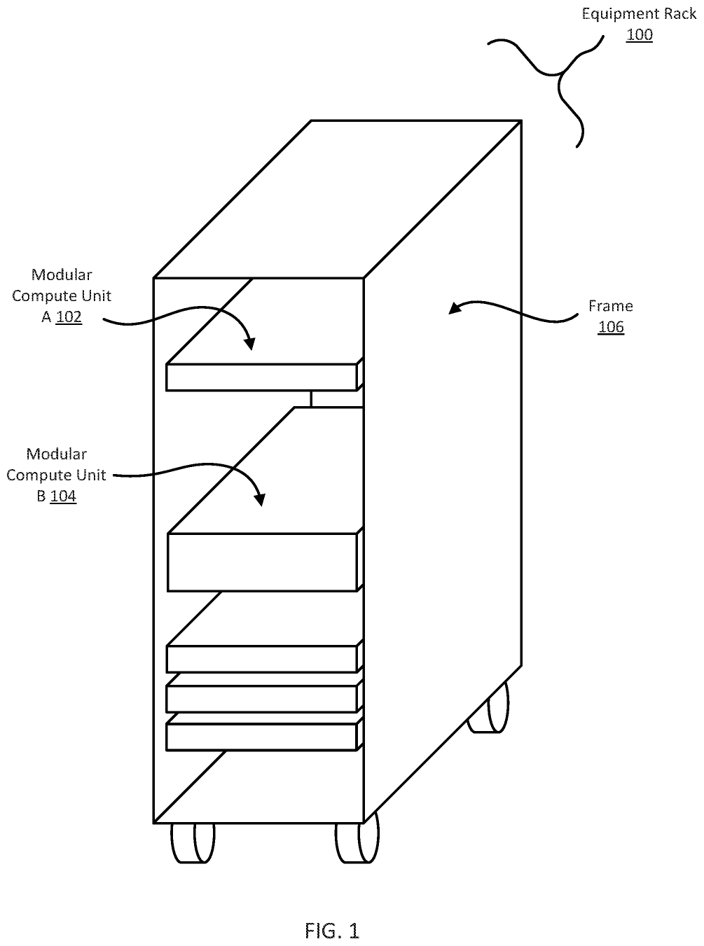

FIG. 1 shows an example equipment rack in accordance with one or more embodiments of the invention. The equipment rack (100) may include a frame (106) and one or more modular compute unit(s) (e.g., modular compute unit A (102), modular compute unit B (104)). The components of the example equipment rack (100) may include mounting capabilities to mount one or more modular compute unit(s) (102, 104). By doing so, devices may be stacked in a high-density computing environment.

In one or more embodiments of the invention, the equipment rack (100) is a physical structure. The equipment rack (100) may include a frame (e.g., frame (106)) that may be adapted to facilitate storage of one or more modular compute unit(s) (102, 104) in a high-density computing environment. The high-density computing environment may be, for example, a data center or another type of location where one or more modular compute unit(s) (102, 104) are located.

The frame (106) may be constructed using any number of suitable materials. For example, portions of the frame (106) may be implemented using metals (e.g., steel, aluminum, etc.). In another example, portions of the frame (106) may be implemented using polymers (e.g., polyamides, polycarbonates, polyester, polyethylene, polypropylene, polystyrene, polyurethanes, polyvinyl chloride, etc.). As another example, portions of the frame (106) may be implemented using rubber (e.g., latex, styrene-butadiene rubbers, etc.). One of ordinary skill in the art, having the benefit of this detailed description, would appreciate that the frame (106) may be implemented using any quantity and combination of suitable materials without departing from the scope of this invention.

To facilitate mounting of one or more modular compute unit(s) (102, 104), the frame (106) may include any number of structural members (e.g., beams, brackets, bars, etc.) and any number of mechanical mounting points (e.g., holes, threaded portions, etc.) disposed on the structural members to facilitate storage of a modular compute unit (102, 104). Different structural members may have different shapes, sizes, and/or other physical characteristics. The shapes, sizes, and/or other physical characteristics of the structural members may be adapted to enable the structural members to be mechanically connected (e.g., permanently or reversibly connected) to each other to form a predetermined structure. The predetermined structure may be, for example, a cage, box, or other type of structure that facilitates positioning and/or orienting one or more modular compute unit(s) (102, 104).

When all, or a portion, of the structural members are mechanically connected to each other, the mechanical mounting points may be disposed at predetermined locations. The predetermined locations may correspond to similar predetermined locations on a modular compute unit (102, 104) where mechanical mounting elements, complementary to the mechanical mounting points, are disposed. By doing so, the frame (106) may be adapted to position a modular compute unit (102, 104) in locations and/or orientations suitable for a high-density computing environment, or another environment in which a modular compute unit (102, 104) may be located. The mechanical mounting points may be any type of physical structure for attaching (permanently or reversibly) a modular compute unit (102, 104) to the frame (106). There may be any number of mechanical mounting points to facilitate the attachment of any number of corresponding modular compute units (102, 104).

To facilitate attachment of a modular compute unit (102, 104) to the frame, a chassis of the modular compute unit (102, 104) may include any number of mechanical mounting elements. The mechanical mounting elements may be located at predetermined locations. For example, a mechanical mounting element may be a rail disposed on a side of a chassis of a modular compute unit (102, 104). The location of the rail may correspond to a position on the frame (106) where a rail guide (i.e., a complementary mechanical mounting point) is disposed. The rail and the rail guide may facilitate attachment of a modular compute unit (102, 104) to the frame (106) which, in turn, positions and orients a modular compute unit (102, 104) relative to the frame (106) and equipment rack (100), generally.

Modular compute units (102, 104) may have different configurations and/or uses within the equipment rack (100). In one or more embodiments of the invention, an equipment rack (100) may include any number and combination of modular compute units (102, 104) adapted for any number of different uses and/or sizes without departing from the scope of the invention. By way of example, modular compute unit A (102) may execute a server for hosting a website, whereas modular compute unit B (104) may host a media server, which stores media files. Further, modular compute unit B (104) may be of a larger physical size than modular compute unit A (102) and, consequently, may be capable of housing more and/or larger modular processing units therein.

While the equipment rack (100) of FIG. 1 has been illustrated as including a limited number of components, an equipment rack (100) in accordance with embodiments of the invention may include any number of frames, modular processing units, and/or other components without departing from the invention. For example, any number of frames (and/or other types of physical devices for positioning/orienting devices) may be used in a high density computing environment to facilitate the placement and/or orientation of any number of modular processing units. Further, the frames may be used to position and/or orient other types of devices. The other types of devices may be, for examples, servers, storage nodes, compute nodes, communication devices (e.g., switches, routers, etc. for facilitating communications between any number of devices and/or devices external to a high density computing environment), or any other type of device that may be used in a computing environment (e.g., data center, computing nodes, communications center, etc.). Thus, the frame may be used in conjunction with any number and/or type of other device without departing from the invention.

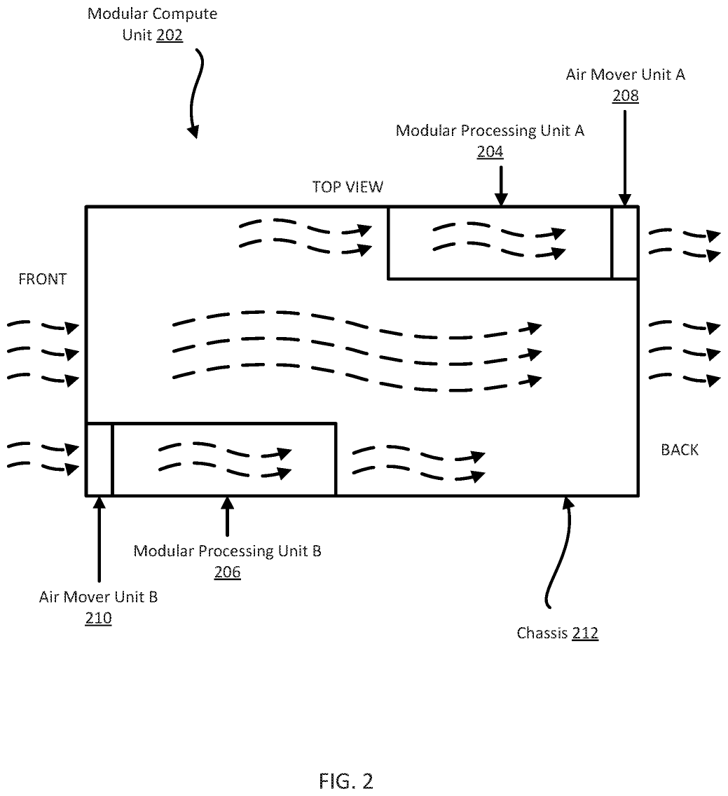

FIG. 2 shows an example modular compute unit, in accordance with one or more embodiments of the invention. Specifically, FIG. 2 shows a top view of a modular compute unit (202) and one or more component(s) therein. In one or more embodiments of the invention, a modular compute unit (e.g., modular compute unit (202)) is physical structure that includes an empty volume suitable to store one or more modular processing unit(s) (e.g., modular processing unit A (204), modular processing unit B (206)) and/or other devices (defined above).

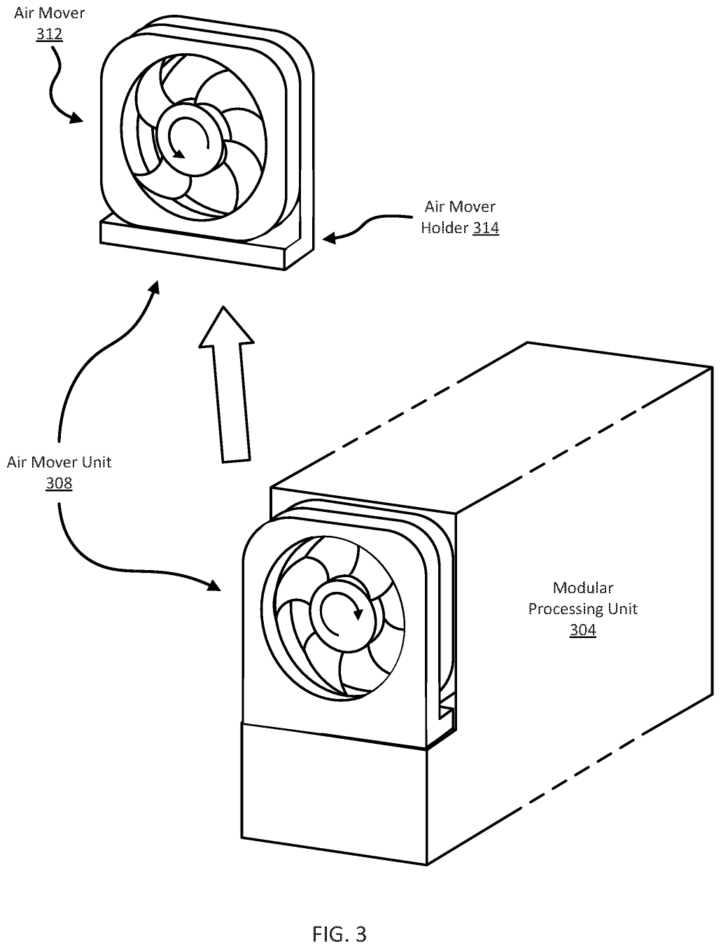

In one embodiment of the invention, a chassis (212) forms the exterior structure of the modular compute unit (202). A chassis (212) may be a mechanical device that is adapted to (i) facilitate attachment of a modular compute unit (202) to a frame of an equipment rack, (ii) house one or more modular processing unit(s) (204, 206), (iii) provide electrical (electrical power and/or data) operative connection(s) to one or more modular processing unit(s) (204, 206), and/or (iv) provide thermal management services to one or more modular processing unit(s) (204, 206) of the modular compute unit (202). More detail regarding the description of a modular processing unit (204, 206) and the components therein is provided in the description of FIGS. 3-5.

The chassis (212) of the modular compute unit (202) may be constructed using any number of suitable materials. For example, portions of the chassis (212) may be implemented using metals (e.g., steel, aluminum, etc.). In another example, portions of the chassis (212) may be implemented using polymers (e.g., Polyamides, polycarbonates, polyester, polyethylene, polypropylene, polystyrene, polyurethanes, etc.). In a still further example, portions of the chassis (212) may be implemented using rubber (e.g., latex, styrene-butadiene rubbers, etc.) The chassis (212) may be implemented using any quantity and combination of suitable materials without departing from the invention.

To house the one or more modular processing unit(s) (204, 206), the chassis (212) may include one or more internal volumes. For example, the internal volumes may facilitate disposing of the one or more modular processing unit(s) (and/or other devices) within a modular compute unit (202). The internal volumes may have a shape or other characteristic(s) that facilitates disposing of the one or more modular processing unit(s). For example, an internal volume of the chassis (212) may be a rectangular void capable of housing one or more modular processing unit(s) (204, 206) and/or other devices. In one embodiment of the invention, a chassis (212) may provide one or more exterior sides (e.g., exterior walls) that form the outer structure of the modular compute unit (202). In one embodiment of the invention, the exterior sides provide mounting points (e.g., holes, threaded portions, etc.) and/or other means for affixing one or more modular processing unit(s) (204, 206) to the inside of the modular compute unit (202).

In one embodiment of the invention, a modular compute unit (202) provides electrical power (e.g., power) to one or more modular processing unit(s) (204, 206) via one or more conductive operative connection(s) (e.g., metallic contacts and/or wire(s) terminated with a plug and socket). In turn, in one embodiment of the invention, one or more modular processing unit(s) (204, 206) provides power to one or more components of the modular processing unit (e.g., air mover unit A (208), air mover unit B (206)). The modular compute unit (202) may be provided power from an equipment rack (not shown) or via some other source.

To provide thermal management services to one or more modular processing unit(s) (204, 206) and/or other devices, a modular compute unit (202) may facilitate the flow of gas proximate to the one or more modular processing unit(s) (204, 206) and/or other devices. By doing so, the thermal state (i.e., temperature) of the aforementioned devices may be regulated (i.e., maintained within a preferred temperature range).

For example, a modular compute unit (202) may include one or more vents that allow a gas from a first side (e.g., “front”) of a modular compute unit (202) to flow into, through, and out a second side (e.g., “back”) of the a modular compute unit (202). The gas, flowing through the modular compute unit (202), may be at a different temperature than the modular processing unit(s) (204, 206) and/or other devices. Consequently, thermal exchange between the flow of gas and the aforementioned devices may occur resulting in the temperature of the aforementioned devices changing. By doing so, heat generated by the aforementioned devices may be expelled from the devices thereby regulating the temperature of the aforementioned devices.

For the example modular compute unit (202) shown in FIG. 2, the gas is shown flowing from a “front” (i.e., left side of FIG. 2) of the modular compute unit (202) to a “back” (i.e., right side of FIG. 2) of the modular compute unit (202). However, the direction of gas flow through the modular compute unit (202) may be controlled by one or more air movers (not shown) that control the flow of the surrounding gas. Accordingly, although the gas is shown in FIG. 2 to be flowing from front-to-back (i.e., left-to-right), reversing the direction in which one or more air mover(s) force gas to flow may cause the gas to flow in the opposite direction (back-to-front, right-to-left). One of ordinary skill in the art, having the benefit of this detailed description, would appreciate that the gas may flow in any direction suitable to the construction of the modular compute unit (202).

As shown in FIG. 2, a modular processing unit (204, 206) may be disposed at the “front” (i.e., left side of FIG. 2) or at the “back” (i.e., right side of FIG. 2) of the modular compute unit. Further, in one embodiment of the invention, as shown in FIG. 2, the air mover unit (208, 210) of the modular processing unit (204, 206) is disposed on the exterior of the chassis (212) regardless of which side (front or back) the modular processing unit (204, 206) is located.

Further, in one embodiment of the invention, like the modular compute unit (202), a modular processing unit (204, 206) provides thermal management services to one or more electronic component(s) (not shown) within the modular processing unit. A modular processing unit (204, 206) may facilitate the flow of gas proximate to the one or more electronic component(s) and/or other devices by including one or more vents that allow a gas from a first side (e.g., “front”) of a modular processing unit (204, 206) to flow into, through, and out a second side (e.g., “back”) of the modular processing unit (204, 206). The gas, flowing through the modular processing unit (204, 206), may be at a different temperature than the modular processing unit(s) (204, 206) and/or other devices. Consequently, thermal exchange between the flow of gas and the aforementioned devices may occur resulting in the temperature of the aforementioned devices changing. By doing so, heat generated by the aforementioned devices may be expelled from the devices thereby regulating the temperature of the aforementioned devices.

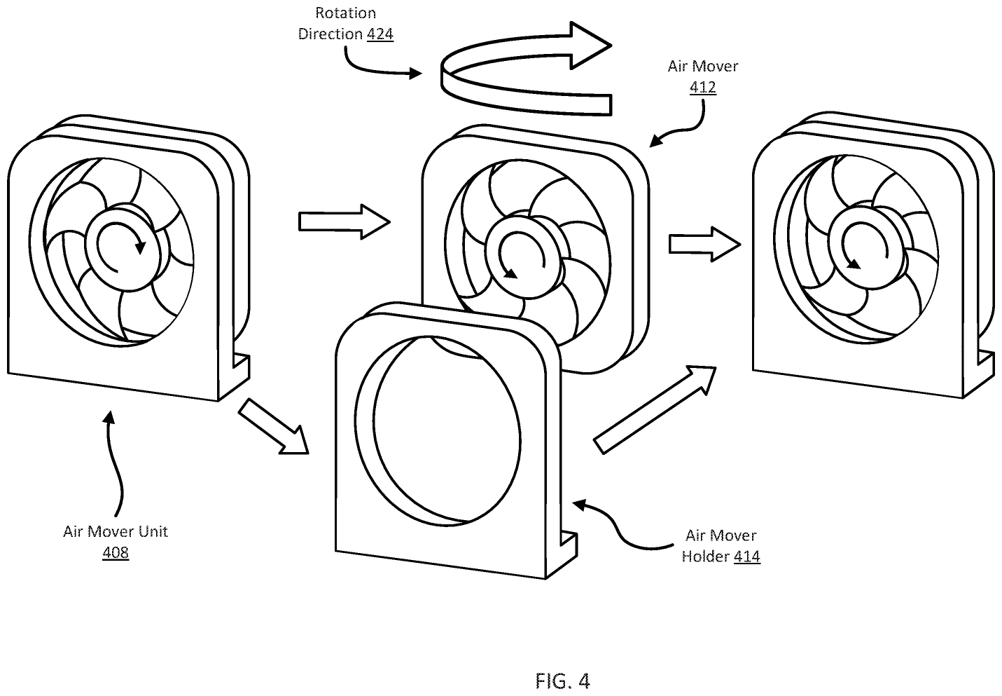

Accordingly, in one embodiment of the invention, the air mover (not shown) (of the air mover unit (208, 210)) is re-oriented such that the air mover causes gaseous matter to flow in the same direction as caused by other air movers (not shown) already operating in the modular compute unit (202). Thus, an air mover may need to be reversed depending on (i) the default orientation of the air mover, (ii) the direction of gaseous flow in the modular compute unit (202), and/or (iii) whether the modular processing unit (204, 206) is installed in the front or back of a modular compute unit (202). More detail regarding the description of reversing the air mover is provided in the description of FIG. 4.

While FIG. 2 shows an example of modular compute unit, other configurations may be used without departing from the scope of the invention. For example, although the two modular processing units (204, 206) are shown to be in the corners of the modular compute unit (202), a modular processing unit may located anywhere within a modular compute unit (e.g., adjacent to only one wall of the chassis (212), or not in contact with any wall of chassis (212)). Accordingly, embodiments disclosed herein should not be limited to the configuration of devices and/or components shown in FIG. 2.

FIG. 3 shows a diagram of an exterior of a modular processing unit, in accordance with one or more embodiments of the invention. As shown in FIG. 3, a modular processing unit (e.g., modular processing unit (304)) may include an air mover unit (e.g., air mover unit (308)) disposed on its exterior.

In one or more embodiments of the invention, the modular processing unit (304) may include any number of structural members (e.g., beams, brackets, bars, etc.) and any number of mechanical mounting points (e.g., holes, threaded portions, etc.) disposed on the structural members to facilitate the attachment of an air mover unit (308). Different structural members may have different shapes, sizes, and/or other physical characteristics. The shapes, sizes, and/or other physical characteristics of the structural members may be adapted to enable the structural members to be mechanically connected to each other to form a predetermined structure. The predetermined structure may be, for example, a cavity, cutout, or other type of structure that facilitates positioning, orienting, and/or attaching the air mover unit (308) to the modular processing unit (304).

When all, or a portion, of the structural members are mechanically connected to each other, the mechanical mounting points of the modular processing unit (304) may be disposed at predetermined locations. The predetermined locations may correspond to similar predetermination locations on the air mover unit (308) where mechanical mounting elements, complementary to the mechanical mounting point of the modular processing unit (304) are disposed. The mechanical mounting points may be any type of physical structure for removably attaching an air mover unit (308) to a modular processing unit (304).

For example, an air mover unit (308) may attach to a modular processing unit (304) via rigid fasteners (e.g., screws, nails, pins, etc.) that traverse one or more aligned mechanical mounting points of the modular processing unit (304) and air mover unit (308). As another example, an air mover unit (308) may attach to a modular processing unit (304) via mechanical latching means (e.g., clip(s), sliding rails) that utilize the elasticity (e.g., flexibility) and/or shape of the materials of the air mover unit (308) and/or modular processing unit (304) to removably attach the two devices (304, 308). As another example, an air mover unit (308) may attach to a modular processing unit (304) via the material properties of some intermediary fixing means (e.g., adhesive tape, hook-and-loop fasteners, etc.) affixed to one or more surface(s) of the air mover unit (308) and/or modular processing unit (304). One of ordinary skill in the art, having the benefit of this detailed description, would appreciate that any fixing means suitable to attach two physical objects may be utilized to affix an air mover unit (308) to a modular processing unit (304).

In one or more embodiments of the invention, an air mover unit (e.g., air mover unit (308)) includes an air mover (312) and an air mover holder (314). In one embodiment of the invention, an air mover unit (308) (and the components thereof) is used to control, generate, or otherwise manage the flow of gaseous matter within the modular processing unit (304). More detail regarding the description of an air mover unit (308), air mover (312), and air mover holder (314) is provided in the description of FIG. 4.

While FIG. 3 shows a specific configuration of a modular processing unit, other configurations may be used without departing from the scope of the invention. For example, although the description of FIG. 3 only describes the means for fixing the air mover unit (308), generally, to the modular processing unit (304)—that same description applies equally to any means for affixing the air mover holder (314) (of the air mover unit (308)) to the modular processing unit (304). Accordingly, embodiments disclosed herein should not be limited to the configuration of devices and/or components shown in FIG. 3.

FIG. 4 shows a diagram of an air mover unit, in accordance with one or more embodiments of the invention. As shown in FIG. 4, an air mover unit (e.g., air mover unit (408)) may include an air mover (e.g., air mover (412)) and air mover holder (e.g., air mover holder (414)).

In one or more embodiments of the invention, an air mover (e.g., air mover (412)) is used to control, generate, or otherwise manage the flow of gaseous matter within a volume. For example, an air mover (412) may be used to generate a flow of surrounding gaseous matter through the volume of a device (e.g., a modular processing unit) that is unoccupied by solid matter. That is, an air mover (412) can direct and/or generate the flow of gaseous matter across one or more surface(s) of solid matter that is surrounded by that gaseous matter. Lastly, an air mover may force gaseous matter across the surface of solid matter by either sucking-in or blowing-out that gaseous matter. One of ordinary skill in the art, having the benefit of this detailed description, would appreciate the basic principles and operation of an air mover (e.g., air mover (412)).

Accordingly, in one embodiment of the invention, an air mover (412) may be used to force the convection (i.e., thermal exchange via surrounding fluidic matter) on one or more devices thereby expediting the rate at which that device is brought to an equilibrium temperature. One of ordinary skill in the art, having the benefit of this detailed description, would appreciate the process of expediting thermal exchange via the use of an air mover (e.g., air mover (412)).

Examples of an air mover (412) include a fan, a valve to control flow between two gaseous volumes of differing pressure, and/or any other means for controlling, generating, or otherwise managing the flow of gaseous matter. As shown in FIG. 4, air mover (412) is depicted as a fan that includes blades and an indicated spin direction. Further, although referred to as an “air mover” herein, an air mover may be used to control, generate, or otherwise manage any gaseous matter (not just “air”).

In one embodiment of the invention, an air mover (412) uses electrical power (e.g., “power”) to operate one or more components to manage the flow of gaseous matter. For example, a fan may use a direct current (DC) motor operatively connected to the blades of the fan to generate a rotational motion. Similarly, a valve may utilize an electrically powered solenoid to control gaseous flow between two volumes of differing pressure. In one embodiment of the invention, power may be provided to the air mover (412) via a conductive operative connection (not shown) (via e.g., metallic contacts and/or wire(s) terminated with a plug and socket) with the air mover holder (414). Alternatively, power may be provided to the air mover (412) via a conductive operative connection with the modular processing unit (not shown).

In one or more embodiments of the invention, an air mover (412) may be designed and/or designed to operate such that the air mover (412) can only control, generate, or otherwise manage the flow of gaseous matter in one direction. For example, the blades of a fan may be contoured to more efficiently ‘push’ gaseous matter when the blades are rotated in a particular direction, thereby forcing gaseous flow in that one direction. That is, although it may be possible to ‘reverse’ the direction of the fan by reversing the polarity of the DC motor that rotates the blades, those blades (when spun in the opposite direction) would not be as efficient at controlling the flow of gaseous matter. Accordingly, ‘reversing an air mover (412)’ may include physically reversing the air mover (412) (e.g., rotating, flipping, etc.), independently of other components, to align the one direction (the air mover (412) is designed to operate at) with the gaseous flow direction of a larger system.

In one or more embodiments of the invention, an air mover holder (e.g., air mover holder (414)) is a physical device to which the air mover (412) may be affixed. In one embodiment of the invention, an air mover holder (414) is a solid bracket that removably affixes to both an air mover (412) and a modular processing unit (not shown) (as discussed in the description of FIG. 3). Further, as discussed in above in the description of FIG. 3 regarding means for affixing an air mover unit (408) to a modular processing unit, those same fixing means are similarly applicable to the attachment of an air mover (e.g., air mover (412)) to an air mover holder (e.g., air mover holder (414)).

In one or more embodiments of the invention, an air mover holder (414) provides a conductive operative connection to the air mover (412) to provide the air mover (412) electrical power to operate. In one embodiment of the invention, the air mover holder (414) may be provided power via one or more conductive operative connections with the modular processing unit (not shown) in order to provide power to the air mover (412).

In one or more embodiments of the invention, an air mover (e.g., air mover (412)) may be detached from an air mover holder (e.g., air mover holder (414)), reversed, and removably re-attached to an air mover holder (e.g., air mover holder (414)) as depicted in FIG. 4. In one embodiment of the invention, reversing the air mover (412) includes rotating the air mover 180° about an axis orthogonal to the direction of gaseous flow.

As shown in FIG. 4, rotating the air mover (412) in the rotation direction (424) would cause the air mover (412) to rotate about a vertical axis. As the vertical axis is orthogonal to the direction of gaseous flow along the stacked axis (i.e., the axis that would protrude into the dimension normal to the surface of FIG. 4), the air mover (412) would be oriented such that the blades of the air mover (412) would spin in the opposite direction (and therefore generate a flow of gaseous matter in an opposite direction (i.e., 180°)) as compared to the direction of forced gaseous flow prior to the air mover's (412) reversal. Alternatively, the air mover (412) may be rotated about of horizontal axis to achieve the same result (i.e., reversing the spin direction of the air mover (412)).

Further, in one embodiment of the invention, both sides of an air mover (412) that are normal to the direction of gaseous flow are constructed to include all of the same mounting and/or fixing capabilities. Accordingly, after reversal, the air mover (412) may be reattached to the air mover holder (414) in the same manner as mounted prior to reversal.

In one or more embodiments of the invention—after the air mover (412) is detached, reversed, and re-attached—the air mover holder (414) may be attached, or re-attached, to a modular processing unit (not shown). Further, in one embodiment of the invention, an air mover (412) may be detached, reversed, and re-attached to an air mover holder (414) while the air mover holder remains attached to a modular processing unit (not shown).

Accordingly, by reversing the orientation of the air mover (412), the modular processing unit may be installed in an orientation that matches the gaseous flow already existing in the modular compute unit.

While FIG. 4 shows a specific configuration of an air mover unit, other configurations may be used without departing from the scope of the invention. Accordingly, embodiments disclosed herein should not be limited to the configuration of devices and/or components shown in FIG. 4.

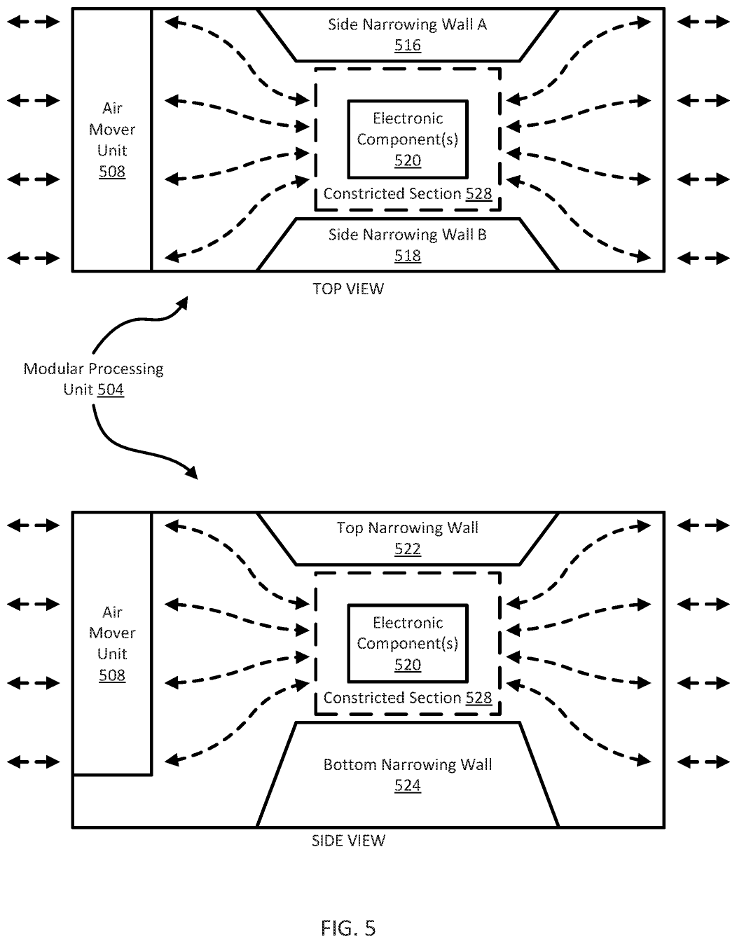

FIG. 5 shows a diagram of a modular processing unit, in accordance with one or more embodiments of the invention. As shown in FIG. 5,a modular processing unit (e.g., modular processing unit (504)) may include an air mover unit (e.g., air mover unit (508)), one or more electronic component(s) (e.g., electronic component(s) (520)), and narrowing walls (e.g., side narrowing wall A (516), side narrowing wall B (518), top narrowing wall (522), bottom narrowing wall (524)).

In one or more embodiments of the invention, an air mover unit (e.g., air mover unit (508)) is substantially similar to the air mover unit discussed in the description of FIGS. 2-4.

In one or more embodiments of the invention, one or more electronic components (e.g., electronic components (520)) are electrically powered and/or operated circuitry. In one embodiment of the invention, electronic components (520) are operatively connected to other components of the modular processing unit (504), the modular compute unit (not shown), and/or the rack (not shown). Although not shown in FIG. 5, one or more electronic components (520) may be operatively connected via physical wires to receive power, and/or transmit and/or receive data to the one or more electronic components (520).

In one or more embodiments of the invention, one or more electronic components (520) may generate heat. Further, in one embodiment of the invention, one or more electronic components (520) may be less efficient at hotter temperatures and therefore, it may be preferable to maintain one or more electronic components (520) at comparatively colder temperatures via forced convection of colder surrounding gaseous matter (as described in the discussion of FIG. 4).

Non-limiting examples of one or more electronic components (520) include integrated circuit storage devices (e.g., solid-state drive (SSD), M.2, Non-Volatile Memory Express (NVMe), flash memory, random access memory (RAM), dynamic RAM (DRAM), resistive RAM (ReRAM), etc.), processors, and other integrated circuits.

In one or more embodiments of the invention, narrowing walls (e.g., side narrowing wall A (516), side narrowing wall B (518), top narrowing wall (522), bottom narrowing wall (524)) may be constructed on the interior of the modular processing unit (504). In one embodiment of the invention, narrowing walls (516, 518, 522, 524) direct the flow of gaseous matter (caused by an air mover of air mover unit (508)) into a constricted section (528) (i.e., a smaller cross-section of the open volume). Thus, assuming a constant mass rate flow through the modular processing unit (504), the gaseous matter that flows through the constricted section (528) passes through at a faster velocity matter than if the narrowing walls (516, 518, 522, 524) were not present to form the constricted section (528).

As discussed in the description of one or more electronic component(s) (520), it may be preferable to maintain one or more electronic components (520) at relatively cooler temperatures via forced convection (as described in the discussion of FIG. 4). In one or more embodiments of the invention, as the narrowing walls (516, 518, 522, 524) force more gaseous matter to traverse a smaller volume, the rate of thermal exchange would increase (e.g., exchanging heat from one or more electronic component(s) (520) to the surrounding gas) thereby further causing one or more electronic component(s) to cool faster, to a lower temperature, or some combination thereof.

While FIG. 5 shows a specific configuration of a modular processing unit, other configurations may be used without departing from the scope of the invention. Accordingly, embodiments disclosed herein should not be limited to the configuration of devices and/or components shown in FIG. 5.

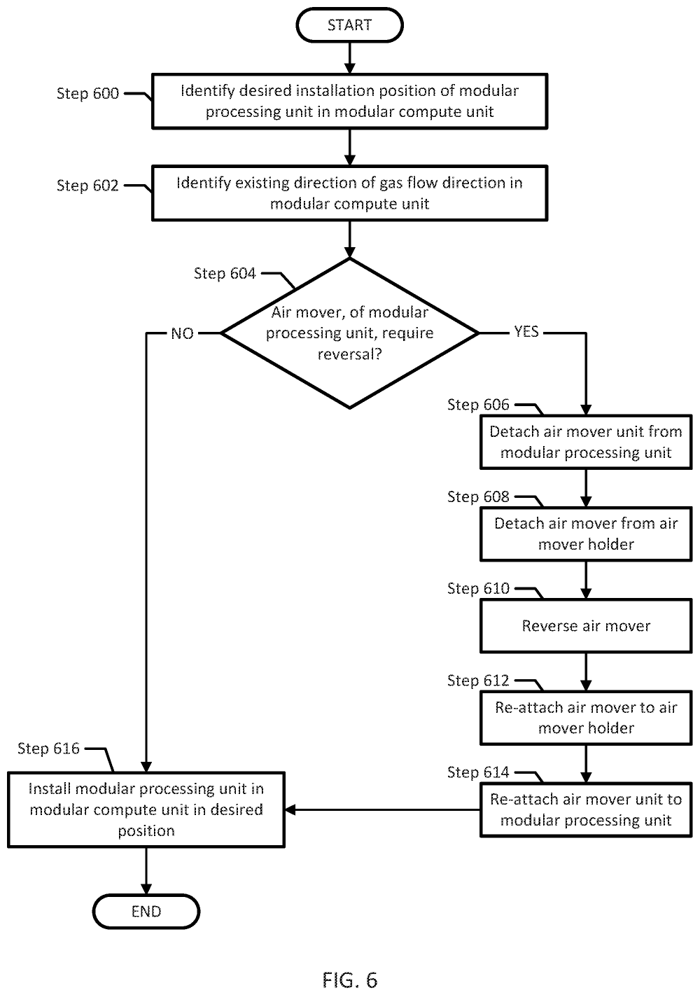

FIG. 6 shows a flowchart of a method of installing a modular processing unit, in accordance with one or more embodiments of the invention. All or a portion of the method shown in FIG. 6 may be performed by one or more users, clients, system administrators, and/or installers of a modular compute unit. However, another person may perform this method without departing from the invention. While the various steps in this flowchart are presented and described sequentially, one of ordinary skill in the relevant art will appreciate that some or all of the steps may be executed in different orders, may be combined or omitted, and some or all steps may be executed in parallel.

In Step 600, one or more user(s) (e.g., a robotic arm under the control of a person, a system administrator, and/or an installer) identifies a desired location and orientation to install a modular processing unit in a modular compute unit. In one embodiment of the invention, a modular processing unit is installed such that the air mover unit of the modular processing unit is disposed against an exterior surface of the modular compute unit. Further, in one embodiment of the invention, the air mover unit is install disposed against a “front” or back” of a modular compute unit (i.e., where the vents of the

In Step 602, the direction of gaseous flow existing in the modular compute unit is identified. In one or more embodiments of the invention, the modular compute unit may already include one or more air movers and/or hardware components that include an air mover. As the already-existing air movers are oriented to guide (and/or force, direct, manage, etc.) gaseous matters to flow in a certain direction, a predetermined gaseous flow direction will already exist within the modular compute unit.

In Step 604, a determination is made as to whether the air mover of the modular processing unit, if installed in the desired orientation (as determined in Step 600), is oriented to guide gaseous matter in the same direction as already existing within the modular compute unit (or, if not, require reversal). In one embodiment of the invention, the modular processing unit is provided to a user with the air mover installed on the modular processing unit. Accordingly, the installed direction of the air mover may not match the already-existing gaseous flow direction within the modular compute unit and will therefore need to be reversed prior to the installation of the modular processing unit.

If the air mover is oriented to guide gaseous matter in the same direction as already existing within the modular compute unit (604-NO), the process proceeds to Step 616. Alternatively, if the air mover is not oriented to guide gaseous matter in the same direction as already existing within the modular compute unit (604-YES), the process proceeds to Step 606.

In Step 606, the air mover unit is detached from the modular processing unit. In one or more embodiments of the invention, the air mover unit may be detached from the modular processing unit by reversing the method(s) used to initially attach the air mover unit and modular processing unit (e.g., unscrewing, unlatching, unclipping, etc.).

In Step 608, the air mover is detached from the air mover holder. In one or more embodiments of the invention, the air mover may be detached from the air mover holder by reversing the method(s) used to initially attach the air mover and air mover holder (e.g., unscrewing, unlatching, unclipping, etc.). In one embodiment of the invention, it may be necessary to first detach the air mover unit from the modular processing unit prior to detaching the air mover from the air mover holder. Alternatively, in one embodiment of the invention, it may be possible to detach the air mover from the air mover holder without first detaching the air mover unit from the modular processing unit.

In Step 610, the air mover is reversed. In one or more embodiments of the invention, reversing the air mover includes rotating the air mover 180° about an axis orthogonal to the direction of gaseous flow. Accordingly, once reversed, the air mover will guide (and/or force, direct, manage, etc.) gaseous matter in a direction 180° opposite to the prior direction.

In Step 612, the air mover is re-attached to the air mover holder. In one or more embodiments of the invention, the air mover may be re-attached to the air mover holder by reversing the method(s) used to detach the air mover and air mover holder (e.g., those of Step 608). In one embodiment of the invention, it may be possible to re-attach the air mover to the air mover holder while the air mover holder is still attached to the modular processing unit (in the event that the air mover unit was not detached from the modular processing unit (Step 606)).

In Step 614, the air mover unit is re-attached to the modular processing unit. In one or more embodiments of the invention, the air mover unit may be re-attached to the modular processing unit by reversing the method(s) used to detach the air mover unit and modular processing unit (e.g., those of Step 606).

In Step 616, the modular processing unit is installed in the modular compute unit in the desired orientation. In one or more embodiments of the invention, as the air mover either (i) did not need to be reversed (Step 604-NO), or (ii) needed to be reversed (604-YES) and was subsequently reversed (Steps 606-614), the modular processing unit may be installed such that components thereof (i.e., the air mover) are oriented consistent with the gaseous flow direction of the modular compute unit.

In one embodiment of the invention, installing the modular processing unit in the modular compute unit includes affixing the modular processing unit to the chassis of the modular compute unit via one or means for attaching (as discussed in the description of FIG. 2).

While one or more embodiments have been described herein with respect to a limited number of embodiments and examples, one of ordinary skill in the art, having the benefit of this detailed description, would appreciate that other embodiments can be devised which do not depart from the scope of the embodiments disclosed herein. Accordingly, the scope should be limited only by the attached claims.

What is claimed is:

1. An equipment rack, comprising:
a modular compute unit;
a modular processing unit disposed in the modular compute unit;
an air mover unit disposed in the modular processing unit, comprising:
an air mover; and
an air mover holder.

2. The equipment rack of claim 1, wherein the air mover is removably attached to the air mover holder.

3. The equipment rack of claim 2, wherein the air mover is oriented to align with a direction of gaseous flow of the modular compute unit.

4. The equipment rack of claim 2, wherein the air mover unit is removably attached to the modular processing unit.

5. The equipment rack of claim 4, wherein the modular processing unit is configured to require detaching the air mover unit from the modular processing unit prior to detaching the air mover.

6. The equipment rack of claim 4, wherein the air mover is a fan.

7. The equipment rack of claim 4, wherein the modular processing unit is disposed on an exterior side of the modular compute unit.

8. The equipment rack of claim 7, wherein the air mover is disposed on the exterior side of the modular compute unit.

9. The equipment rack of claim 4, wherein the modular compute unit comprises a second modular processing unit, wherein the second modular processing unit is oriented in an opposite direction to the modular processing unit with respect to the modular compute unit, wherein the second modular processing unit comprises a second air mover, and wherein the second air mover is oriented in a same direction as the air mover with respect to the modular compute unit.

10. The equipment rack of claim 1, wherein the modular processing unit comprises narrowing walls that form a constricted section.

11. The equipment rack of claim 10, wherein the modular processing unit comprises an electronic component disposed in the constricted section.

12. A method for installing a modular processing unit in a modular compute unit, comprising:
identifying a desired orientation of the modular processing unit;
identifying a gaseous flow direction of the modular compute unit;
making a determination, based on the desired orientation and the gaseous flow direction, that an air mover of the modular processing unit needs to be reversed;
reversing, based on the determination, the air mover; and
affixing the modular processing unit to the modular compute unit.

13. The method of claim 12, wherein reversing the air mover comprises:
detaching the air mover from the modular processing unit;
rotating the air mover 180° about an axis orthogonal to a direction of gaseous flow; and
reattaching the air mover to the modular processing unit.

14. The method of claim 13, wherein reversing the air mover further comprises:
prior to detaching the air mover from the modular processing unit:
detaching an air mover unit from the modular processing unit, wherein the air mover unit comprises the air mover and an air mover holder; and
wherein reattaching the air mover to the modular processing unit comprises:
reattaching the air mover to the air mover holder; and
reattaching the air mover unit to the modular processing unit.

15. The method of claim 13, wherein affixing the modular processing unit to the modular compute unit comprises:
affixing the modular processing unit to an interior of the modular compute unit.

16. The method of claim 15, wherein the modular processing unit is affixed to an exterior side of the interior of the modular processing unit.

17. The method of claim 16, wherein the air mover is disposed on the exterior side of the interior of the modular processing unit.

18. The method of claim 13, wherein the method further comprises:
making a second determination, based on the desired orientation and the gaseous flow direction, that a second air mover of a second modular processing unit does not need to be reversed; and
affixing, based on the determination, the second modular processing unit to the modular compute unit.

19. The method of claim 18, wherein the second air mover is oriented opposite the air mover.

20. The method of claim 19, wherein the modular processing unit is disposed on a first exterior side of the modular compute unit, wherein the second modular processing unit is disposed on a second exterior side of the modular compute unit, wherein the second exterior side is opposite the first exterior side.
